(19) United States
(12) Patent Application Publication
(10) Pub. No.: US 2023/0329098 A1
(43) Pub. Date: Oct. 12, 2023

(54) MATERIAL FOR FORMING BLUE LIGHT-EMITTING LAYER, LIGHT-EMITTING DEVICE, LIGHT-EMITTING SUBSTRATE, AND LIGHT-EMITTING APPARATUS

(71) Applicant: BOE TECHNOLOGY GROUP CO., LTD., Beijing (CN)

(72) Inventors: Xueqin CHEN, Beijing (CN); Yang LIU, Beijing (CN)

(73) Assignee: BOE TECHNOLOGY GROUP CO., LTD., Beijing (CN)

(21) Appl. No.: 17/927,498

(22) PCT Filed: Nov. 8, 2021
(86) PCT No.: PCT/CN2021/129334

§ 371 Date: Nov. 23, 2022

(30) Foreign Application Priority Data
Jan. 25, 2021 (CN) 202110098176.5

(51) Int. Cl. H10K 85/60; H10K 50/12

(52) U.S. Cl. CPC H10K 85/657; H10K 50/12; H10K 85/615

(57) ABSTRACT

A material for forming a blue light-emitting layer, comprising: a main material and a dopant material doped in the main material, wherein there is an overlapping region between the normalized fluorescence emission spectrum of the main material and the normalized absorption spectrum of the dopant material, and the integrated area of the overlapping region is greater than or equal to 50% of the integrated area of the normalized fluorescence emission spectrum of the main material.

### CROSS-REFERENCE TO RELATED APPLICATIONS

This application is a national phase entry under 35 USC 371 of International Patent Application No. PCT/CN2021/129334, filed on Nov. 8, 2021, which claims priority to Chinese Patent Application No. 202110098176.5, filed on Jan. 25, 2021, which are incorporated herein by reference in their entirety.

### TECHNICAL FIELD

The present disclosure relates to the fields of lighting and display technologies, and in particular, to a material for forming a blue light-emitting layer, a light-emitting device, a light-emitting substrate, and a light-emitting apparatus.

### BACKGROUND

Organic light-emitting diodes (OLEDs) have characteristics of self-luminescence, wide viewing angle, quick response, high luminous efficiency, low operating voltage, small substrate thickness, being capable of being used for manufacturing a large-sized and bendable substrate, simple manufacturing process and the like, and is known as a next-generation “star” display technology.

### SUMMARY

In an aspect, a material for forming a blue light-emitting layer is provided. The material includes a host material and a dopant material doped in the host material. A normalized fluorescence emission spectrum of the host material and a normalized absorption spectrum of the dopant material have an overlapping region therebetween, an integral area of the overlapping region is greater than or equal to 50% of an integral area of the normalized fluorescence emission spectrum of the host material, and an absolute value of a difference between a wavelength corresponding to a peak of the normalized fluorescence emission spectrum of the host material and a wavelength corresponding to a peak of the normalized absorption spectrum of the dopant material is less than or equal to 30 nm.

In some embodiments, the wavelength corresponding to the peak of the normalized fluorescence emission spectrum of the host material is less than or equal to the wavelength corresponding to the peak of the normalized absorption spectrum of the dopant material.

In some embodiments, a wavelength of the normalized fluorescence emission spectrum of the host material is in a range from 410 nm to 450 nm, and a wavelength of the normalized absorption spectrum of the dopant material is in a range from 430 nm to 455 nm.

In some embodiments, the host material is selected from any one of derivatives of anthracene.

In some embodiments, the host material is selected from any one of structures represented by a following general formula (I).

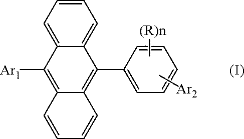

Ar₁ and Ar₂ are the same or different, and are each independently selected from any one of aryl, heteroaryl, fused aryl and fused heteroaryl; R is selected from any one of deuterium, halogen, alkyl, aryl, heteroaryl, fused aryl and fused heteroaryl; n is 0, 1 or 2.

In some embodiments, in a case where Ar₁ is selected from heteroaryl or fused heteroaryl, the heteroaryl and the fused heteroaryl each contain no nitrogen atom; in a case where Ar₂ is selected from heteroaryl or fused heteroaryl, the heteroaryl and the fused heteroaryl each contain no nitrogen atom; in a case where R is selected from heteroaryl or fused heteroaryl, the heteroaryl and the fused heteroaryl each contain no nitrogen atom.

In some embodiments, the host material is selected from any one of structures having following structural formulas:

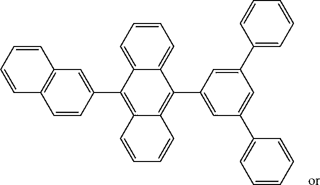

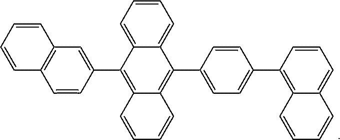

In some embodiments, the dopant material is selected from any one of organoboron compounds.

In some embodiments, the dopant material is selected from any one of structures represented by a following general formula (II).

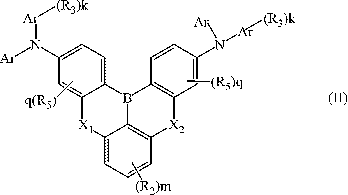

X₁ and X₂ are the same or different, and are each independently selected from any one of C(R₁)₂, N(R₁), C(═O), B(R₁), Si(R₁)₂, C(═N(R₁)), C(═C(R₁)₂), O, S, S(═O), S(═O)₂, P(R₁) and P(═O)(R₁); R₁, R₂, R₃ and R₅ are the same or different, and are each independently selected from any one of deuterium, halogen, alkyl, aryl, heteroaryl, fused aryl and fused heteroaryl; Ar is selected from any one of aryl, heteroaryl, fused aryl and fused heteroaryl; m is 0, 1 or 2, q is 0, 1 or 2, and k is 0, 1 or 2.

In some embodiments, the dopant material is selected from any one of structures having following structural formulas:

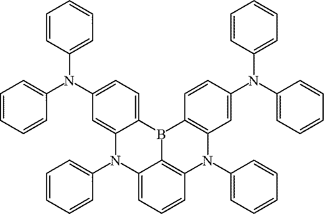 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1]

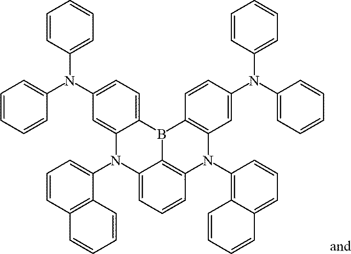

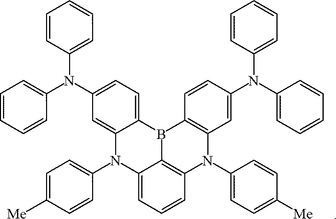

In some embodiments, a mass ratio of the dopant material to the material for forming the blue light-emitting layer is in a range from 0.5% to 8%.

In some embodiments, the mass ratio of the dopant material to the material for forming the blue light-emitting layer is in a range from 1% to 3%.

In another aspect, a light-emitting device is provided. The light-emitting device includes: a first electrode and a second electrode that are arranged sequentially; and a light-emitting layer disposed between the first electrode and the second electrode. The material for forming the blue light-emitting layer as described above is selected as a material of the light-emitting layer.

In some embodiments, the wavelength corresponding to the peak of the normalized fluorescence emission spectrum of the host material is less than or equal to the wavelength corresponding to the peak of the normalized absorption spectrum of the dopant material.

In some embodiments, a wavelength of the normalized fluorescence emission spectrum of the host material is in a range from 410 nm to 450 nm, and a wavelength of the normalized absorption spectrum of the dopant material is in a range from 430 nm to 455 nm.

In some embodiments, the host material is selected from any one of derivatives of anthracene.

In some embodiments, the host material is selected from any one of structures represented by a following general formula (l).

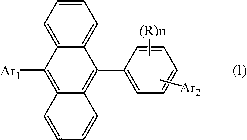

Ar₁ and Ar₂ are the same or different, and are each independently selected from any one of aryl, heteroaryl, fused aryl and fused heteroaryl; R is selected from any one of deuterium, halogen, alkyl, aryl, heteroaryl, fused aryl and fused heteroaryl; n is 0, 1 or 2.

In some embodiments, in a case where Ar₁ is selected from heteroaryl or fused heteroaryl, the heteroaryl and the fused heteroaryl each contain no nitrogen atom; in a case where Ar₂ is selected from heteroaryl or fused heteroaryl, the heteroaryl and the fused heteroaryl each contain no nitrogen atom; in a case where R is selected from heteroaryl or fused heteroaryl, the heteroaryl and the fused heteroaryl each contain no nitrogen atom.

In yet another aspect, a light-emitting substrate is provided. The light-emitting substrate includes a substrate and a plurality of light-emitting devices disposed on the substrate. At least one light-emitting device of the plurality of light-emitting devices is the light-emitting device as described above.

In yet another aspect, a light-emitting apparatus is provided. The light-emitting apparatus includes the light-emitting substrate as described above.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings in the following description may be regarded as schematic diagrams, and are not limitations on actual sizes of products, actual processes of methods and actual timings of signals involved in the embodiments of the present disclosure.

FIG. 1 is a sectional view of a light-emitting substrate, in accordance with some embodiments;

FIG. 2 is a top view of a light-emitting substrate, in accordance with some embodiments,

FIG. 3 is a diagram showing a normalized fluorescence emission spectrum of a host material BH and a normalized absorption spectrum of a dopant material BD, in accordance with some embodiments; and

FIG. 4 is a diagram showing a normalized fluorescence emission spectrum of a host material BH and a normalized absorption spectrum of a dopant material BD, in accordance with the related art.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

Additionally, the phase “based on” as used herein is meant to be open and inclusive, since a process, a step, a calculation or other action that is “based on” one or more of the stated conditions or values may, in practice, be based on additional conditions or values beyond those stated.

As used herein, the term such as “about” or “approximately” includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

Some embodiments of the present disclosure provide a light-emitting apparatus. The light-emitting apparatus includes a light-emitting substrate, and may of course, further include other components such as a circuit used for providing an electrical signal for the light-emitting substrate to drive the light-emitting substrate to emit light. The circuit may be referred to as a control circuit, and may include a circuit board and/or an integrated circuit (IC) that each electrically connected to the light-emitting substrate.

In some embodiments, the light-emitting apparatus may be a lighting apparatus; in this case, the light-emitting apparatus serves as a light source for realizing a lighting function. For example, the light-emitting apparatus may be a backlight module in a liquid crystal display apparatus, a lamp used for internal or external lighting, a signal lamp, etc.

In some other embodiments, the light-emitting apparatus may be a display apparatus; in this case, the light-emitting substrate is a display substrate for realizing a function of displaying images (i.e., pictures). The light-emitting apparatus may include a display or a product including the display. The display may be a flat panel display (FPD), a micro display, etc. The display may be classified as a transparent display or a non-transparent display according to whether a user can see a scene behind the display. The display may be classified as a flexible display or a normal display (which may be also referred to as a rigid display) according to whether the display can be bent or rolled. For example, the product including the display may include a computer display, a television, a billboard, a laser printer having a display function, a telephone, a mobile phone, a personal digital assistant (PDA), a laptop computer, a digital camera, a portable camcorder, a viewfinder, a vehicle, a large-area wall, a screen of a theater or a sign of a stadium.

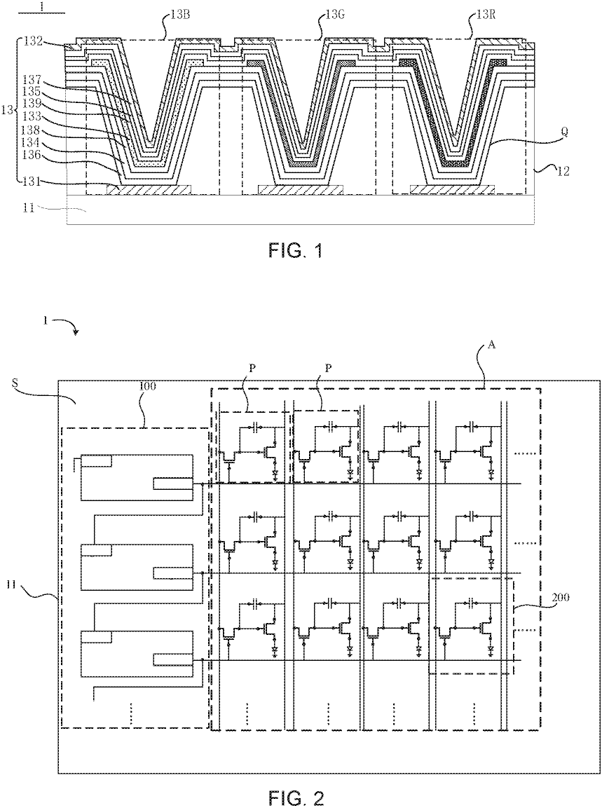

Some embodiments of the present disclosure provide a light-emitting substrate 1, as shown in FIG. 1, the light-emitting substrate 1 includes a substrate 11, and a pixel definition layer 12 and a plurality of light-emitting devices 13 that are disposed on the substrate 11. The pixel definition layer 12 has a plurality of openings Q, and the plurality of light-emitting devices 13 may be arranged in a one-to-one correspondence with the plurality of openings Q. Here, the plurality of light-emitting devices 13 may be all or part of light-emitting devices 13 included in the light-emitting substrate 1; the plurality of openings Q may be all or part of openings in the pixel definition layer 12.

In the plurality of light-emitting devices 13, at least one light-emitting device 13 may include a first electrode 131, a second electrode 132, and a light-emitting layer 133 disposed between the first electrode 131 and the second electrode 132. Each light-emitting layer 133 may include a portion located in an opening Q. In the at least one light-emitting device 13, a material of the light-emitting layer 133 may be selected from materials for forming a blue light-emitting layer. That is, the at least one light-emitting device 13 is a light-emitting device 13B that emits blue light.

In some embodiments, as shown in FIG. 1, the first electrode 131 may be an anode; in this case, the second electrode 132 is a cathode. In some other embodiments, the first electrode 131 may be a cathode; in this case, the second electrode 132 is an anode.

In some embodiments, a material of the anode may be selected from high work function materials such as indium tin oxide (ITO), indium zinc oxide (IZO) or composite materials (e.g., silver (Ag)/ITO, aluminum (Al)/ITO, Ag/IZO or Al/IZO). “Ag/ITO” refers to a stacked structure stacked by a silver electrode and an ITO electrode. A material of the cathode may be selected from low work function materials such as Al, Ag, magnesium (Mg) or low work function metal alloy materials (e.g., Mg-Al alloy or Mg-Ag alloy).

For a light-emitting device of an organic light-emitting diode (OLED), a light-emitting principle of the light-emitting device 13 is that, through a circuit connected between the anode and the cathode, the anode injects holes into the light-emitting layer 133, the cathode injects electrons into the light-emitting layer 133, the electrons and the holes that are injected form excitons in the light-emitting layer 133, and the excitons are each back to a ground state through a manner of radiative transition, so as to emit photons.

As shown in FIG. 1, in order to improve an efficiency of injecting the electrons and the holes into the light-emitting layer 133, the light-emitting device 13 may further include at least one of a hole transporting layer (HTL) 134, an electron transporting layer (ETL) 135, a hole injection layer (HIL) 136 and an electron injection layer (EIL) 137. For example, the light-emitting device 13 may further include the hole transporting layer (HTL) 134 disposed between the anode and the light-emitting layer 133, and the electron transporting layer (ETL) 135 disposed between the cathode and the light-emitting layer. In order to further improve the efficiency of injecting the electrons and the holes into the light-emitting layer 133, the light-emitting device 13 may further include the hole injection layer (HIL) 136 disposed between the anode and the hole transporting layer 134, and the electron injection layer (EIL) 137 disposed between the cathode and the electron transporting layer 135.

In some embodiments, a material of the electron transporting layer 135 may be selected from organic materials having good electron transmission properties; alternatively, the material of the electron transporting layer 135 may be selected from the organic materials doped with LiQ₃, lithium (Li), calcium (Ca) and the like. A thickness of the electron transporting layer 135 may be in a range from 10 nm to 70 nm. A material of the hole transporting layer 134 may be selected from any one of N,N′-Bis-(1-naphthalenyl)-N,N′-bis-phenyl-(1,1′-biphenyl)-4,4′-diamine and 4,4′-cyclohexylidenebis[N,N-bis(p-tolyl)aniline].

In some other embodiments, a material of the electron injection layer 137 may be selected from low work function metals such as Li, Ca and ytterbium (Yb); alternatively, the material of the electron injection layer 137 may be selected from metal salts such as lithium fluoride (LiF) and LiQ₃. A thickness of the electron injection layer 137 may be in a range from 0.5 nm to 2 nm. A material of the hole injection layer 136 may be selected from copper(II) phthalocyanine (CuPc), hexaazatriphenylenehexacabonitrile (HATCN) or manganese trioxide (MnO₃); alternatively, the material of the hole injection layer 136 may be selected from materials obtained by performing P-type doping on these materials. A thickness of the hole injection layer 136 may be in a range from 5 nm to 30 nm.

In a process of transporting the holes and the electrons, in order to avoid a problem that a reduction, caused by a fact that the electrons are quenched on a surface of the anode and the holes are quenched on a surface of the cathode, of a recombination efficiency of the electrons and the holes is not conducive to an improvement of a luminous efficiency. In some embodiments, as shown in FIG. 1, the light-emitting device 13 further includes an electron blocking layer (EBL) 138 located between the hole transporting layer 134 and the light-emitting layer 133, and a hole blocking layer (HBL) 139 located between the electron transporting layer 135 and the light-emitting layer 133.

In some embodiments, a material of the electron blocking layer 138 may be selected from any one of 4,4′-cyclohexylidenebis[N,N-bis(p-tolyl)aniline] and 4,4′,4″-Tris(carbazol-9-yl)-triphenylamine. 2,9-dimethyl-4,7-diphenyl-1,10-Phenanthroline may be selected as a material of the hole blocking layer (HBL) 139.

The light-emitting substrate 1 may be further provided with driving circuits connected to respective light-emitting devices 13 therein, and the driving circuits may be connected to the control circuit to drive the respective light-emitting devices 13 to emit light according to the electrical signal input by the control circuit. The driving circuits may be each an active driving circuit or a passive driving circuit.

The light-emitting substrate 1 may emit white light, monochromatic light (i.e., single-color light) or color-tunable light.

In a first example, the light-emitting substrate 1 may emit the white light. In this case, as shown in FIG. 1, in addition to the light-emitting device 13B that emits the blue light, the plurality of light-emitting devices 13 may further include a light-emitting device 13R that emits red light and a light-emitting device 13G that emits green light. In this case, the light-emitting device 13B that emits the blue light, the light-emitting device 13R that emits the red light and the light-emitting device 13G that emits the green light are controlled to emit light simultaneously, which may achieve light mixing of the light-emitting device 13B that emits the blue light, the light-emitting device 13R that emits the red light and the light-emitting device 13G that emits the green light, thereby enabling the light-emitting substrate 1 to emit the white light.

In this example, the light-emitting substrate 1 may be used for lighting. That is, the light-emitting substrate 1 may be applied to a lighting apparatus.

In a second example, the light-emitting substrate 1 may emit the monochromatic light. In this case, according to a fact that the at least one light-emitting device 13 in the plurality of light-emitting devices 13 is the light-emitting device 13B that emits the blue light, it can be seen that the light-emitting substrate 1 may emit the blue light. That is, it is a case where the plurality of light-emitting devices 13 are each the light-emitting device 13B that emits the blue light. In this example, the light-emitting substrate 1 may be used for lighting. That is, the light-emitting substrate 1 may be applied to a lighting apparatus. Alternatively, the light-emitting substrate 1 may be used for displaying images or pictures of a single color. That is, the light-emitting substrate 1 may be applied to a display apparatus.

In a third example, the light-emitting substrate 1 may emit the color-tunable light (i.e., colored light). The plurality of light-emitting devices 13 included in the light-emitting substrate 1 are similar to the plurality of light-emitting devices 13 as described in the first example in structure. A color and luminance of mixed light emitted by the light-emitting substrate 1 may be controlled by controlling luminance of each light-emitting device 13, thereby achieving emitting the colored light.

In this example, the light-emitting substrate 1 may be used for displaying images or pictures. That is, the light-emitting substrate 1 may be applied to a display apparatus. Of course, the light-emitting substrate 1 may be applied to a lighting apparatus.

In the third example, in an example where the light-emitting substrate 1 is a display substrate such as a full color display panel, as shown in FIG. 2, the light-emitting substrate 1 includes a display area A and a peripheral area S disposed around the display area A. The display area A includes a plurality of sub-pixel regions P. Each sub-pixel region P corresponds to an opening, and an opening corresponds to a light-emitting device. Each sub-pixel region P is provided with a pixel driving circuit 200 used for driving a respective light-emitting device to emit light therein. The peripheral region S is used for wiring. For example, the peripheral region S is used for arranging a gate driving circuit 100 connected to the pixel driving circuits 200.

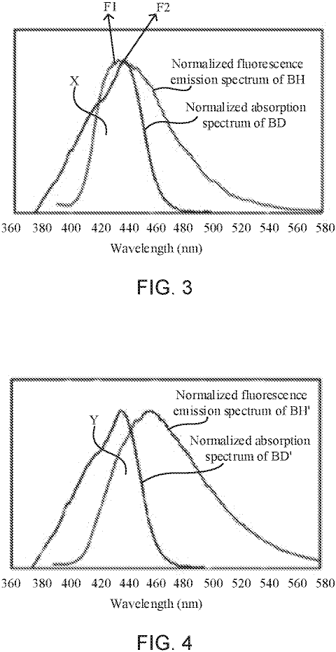

Based on the above structure, some embodiments of the present disclosure provide a material for forming a blue light-emitting layer. The material includes a host material BH and a dopant material BD doped in the host material BH. As shown in FIG. 3, a normalized fluorescence emission spectrum of the host material BH and a normalized absorption spectrum of the dopant material BD have an overlapping region X therebetween, an integral area of the overlapping region X is greater than or equal to 50% of an integral area of the normalized fluorescence emission spectrum of the host material BH.

In order to improve the luminous efficiency, the light-emitting layer 133 emits light by mainly using the material doped by a host material and a guest material. The host material BH is a material having characteristics of a capability to transfer energy with the guest material (which is also referred to as the dopant material BD here), a reversible electrochemical redox reaction, a good and matched capability to transmit the holes and the electrons, a good thermal stability and a good film-forming property, and the host material BH has a relatively large proportion in the light-emitting layer 133. The dopant material BD may be a fluorescent luminescent material, a phosphor luminescent material and the like, and the dopant material BD has a relatively small proportion in the light-emitting layer 133.

The fluorescence resonance energy transfer (which is also referred to as the Forster energy transfer) refers to that, in two different fluorophores, if a fluorescence emission spectrum of one fluorophore (i.e., a donor) and an absorption spectrum of the other fluorophore (i.e., an acceptor) have a certain overlapping region therebetween, in a case where a distance between the two different fluorophores is appropriate (for example, the distance is generally less than 100 Å), a transfer of fluorescence energy from the donor to the acceptor may be observed. That is, upon an excitation with excitation light of the donor, an intensity of fluorescence generated by the donor is much lower than that when the donor is present alone, and fluorescence emitted by the acceptor is greatly enhanced, so that lifetimes of the fluorescence of the donor and the fluorescence of the acceptor are shortened and prolonged, respectively. In short, the fluorescence resonance energy transfer is that energy, mediated by a pair of electric dipoles, is transferred from the donor to the acceptor in an excited state of the donor group, and there is no photon participating in this process, so that the process is non-radiative. After the donor molecule is excited, in a case where there is a certain distance between the acceptor molecule and the donor molecule, and an energy difference between vibrational energy levels of a ground state and an electronic excited state of the donor and an energy difference between vibrational energy levels of a ground state and an electronic excited state of the acceptor are adapted to each other, the donor in the excited state will transfer part or all of energy to the acceptor, so that the acceptor is excited. In the whole process of the energy transfer, emission or re-absorption of the photon are not involved.

With respect to a fluorescence emission spectrum of a luminescent material, the fluorescence emission spectrum refers to an intensity distribution or an energy distribution of light of different wavelengths emitted by the luminescent material upon excitation by light of a particular wavelength. The fluorescence emission spectrum here may be obtained by measuring in a solution through a fluorescence spectrometer.

An absorption spectrum is a spectrogram showing a variation of an absorption coefficient with a wavelength of incident light. Main absorption bands of most luminescent materials are each in an ultraviolet region, and an ultraviolet absorption spectrum of the luminescent material may be measured by an ultraviolet-visible spectrophotometer.

Normalization of a spectrum refers to performing normalization processing on the spectrum, i.e., setting a total light intensity to one to change light intensities on an ordinate into decimals, and thus the obtained spectrum is a normalized spectrum.

According to a mechanism of the Forster energy transfer, since the normalized fluorescence emission spectrum of the host material BH and the normalized absorption spectrum of the dopant material BD have the overlapping region X therebetween, the Forster energy transfer may be caused to occur between the host material BH and the dopant material BD by selecting the host material BH and the dopant material BD that are appropriate. In addition, according to a fact that the integral area of the overlapping region X is greater than or equal to 50% of the integral area of the normalized fluorescence emission spectrum of the host material BH, it can be seen that in a case where the Forster energy transfer occurs between the host material BH and the dopant material BD, the Forster energy transfer may be made sufficiently, thereby greatly improving a luminous efficiency of the dopant material BD. As a result, an efficiency of the light-emitting device 13 may be improved.

Fluorescence emission spectra of many luminescent materials are each a continuous band consisted of one or more curves each in a shape of a peak, and this kind of curve may be expressed by a Gaussian function. Fluorescence emission spectra of some other materials are narrow, even each in a shape of a spectral line.

No matter which of the above fluorescence emission spectra, in some embodiments, as shown in FIG. 3, an absolute value of a difference between a wavelength corresponding to a peak F1 of the normalized fluorescence emission spectrum of the host material BH and a wavelength corresponding to a peak F2 of the normalized absorption spectrum of the dopant material BD is less than or equal to 30 nm. Thus, the energy transfer may be achieved to the greatest extent.

According to the Stokes Law, a material absorbs short wave radiation with high energy and emits long wave radiation with low energy. It can be seen that, as shown in FIG. 3, the wavelength corresponding to the peak F1 of the normalized fluorescence emission spectrum of the host material BH is less than or equal to the wavelength corresponding to the peak F2 of the normalized absorption spectrum of the dopant material BD.

In some embodiments, the dopant material BD may be the fluorescent luminescent material or the phosphor luminescent material. Since the Forster energy transfer is the non-radiative energy transfer, and a transition of the donor molecule from the ground state to the excited state and a transition of the acceptor molecule from the ground state to the excited state both obey the spin conservation rule, it is generally transfer of singlet-state energy between the donor and the acceptor. Therefore, whether the dopant material BD is the fluorescent luminescent material or the phosphor luminescent material, it can be considered that a manner of the energy transfer between the host material BH and the dopant material BD in the light-emitting device is the Forster energy transfer.

In some embodiments, according to a fact that a wavelength of visible light is in a range from 400 nm to 760 nm, and a wavelength of the blue light is in a range from 450 nm to 480 nm, it can be seen that, as shown in FIG. 3, a wavelength of the normalized fluorescence emission spectrum of the host material BH is in a range from 410 nm to 450 nm, and a wavelength of the normalized absorption spectrum of the dopant material BD is in a range from 430 nm to 455 nm. Thus, an emission spectrum of the blue light in which the wavelength is in a range from 450 nm to 480 nm may be obtained.

In some embodiments, the host material BH is selected from any one of derivatives of anthracene.

Anthracene is a fused-ring aromatic compound consisting of three benzene rings that are linearly arranged, and a fluorescence intensity of this kind of compound is relatively high. The derivatives of anthracene each have an unchanged main structure (that is, the three benzene rings are unchanged), some groups are added based on the main structure, and main effects of the derivatives of anthracene are unchanged. Fluorescence emission spectra of the derivatives of anthracene may be each adjusted by adjusting structures of these groups.

In some embodiments, the host material BH is selected from any one of structures represented by a following general formula (l).

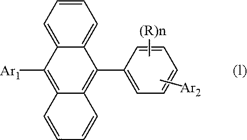

Ar₁ and Ar₂ are the same or different, and are each independently selected from any one of aryl, heteroaryl, fused aryl and fused heteroaryl; R is selected from any one of deuterium, halogen, alkyl, aryl, heteroaryl, fused aryl and fused heteroaryl; n is 0, 1 or 2.

It can be seen from the above that Ar₁, Ar₂ and R are all substituent groups, and the fluorescence emission spectra of the derivatives of anthracene may be each adjusted by adjusting the substituent groups.

The aryl may be phenyl. The heteroaryl may be furyl, pyranyl, thienyl, pyridyl, etc. The fused aryl may be naphthyl, indenyl, anthryl, phenanthryl, etc. The fused heteroaryl may be carbazolyl, benzofuranyl, quinolinyl, acridinyl, etc.

According to a fact that n is 0, 1 or 2, it can be seen that the number of the substituent groups R may be 0, 1 or 2. In a case where the number of substituent groups R is 0, in a benzene ring substituted by the substituent group Ar₂, carbon atoms, except carbon atoms respectively bonded to the anthracene and Ar₂, are each bonded to hydrogen. In a case where the number of substituent groups R is 1, in the benzene ring substituted by the substituent group Ar₂, in the carbon atoms, except the carbon atoms respectively bonded to the anthracene and Ar₂, one carbon atom is bonded to the substituent R, and remaining carbon atoms are each bonded to hydrogen. In a case where the number of substituent groups R is 2, in the benzene ring substituted by the substituent group Ar₂, in the carbon atoms, except the carbon atoms respectively bonded to the anthracene and Ar₂, two carbon atoms are each bonded to the respective substituent R, and remaining carbon atoms are each bonded to hydrogen.

In some embodiments, in a case where Ar₁ is selected from heteroaryl or fused heteroaryl, the heteroaryl and the fused heteroaryl each contain no nitrogen atom; in a case where Ar₂ is selected from heteroaryl or fused heteroaryl, the heteroaryl and the fused heteroaryl each contain no nitrogen atom; in a case where R is selected from heteroaryl or fused heteroaryl, the heteroaryl and the fused heteroaryl each contain no nitrogen atom.

That is, Ar₁, Ar₂ and R are each heteroaryl containing no nitrogen atom or fused heteroaryl containing no nitrogen atom such as carbazolyl. In this way, it is possible to prevent carbon-nitrogen (C—N) bonds from being introduced into the host material BH, so that a problem that a lifetime of the device is reduced caused by a fact that the C—N bonds are prone to be broken under high energy of the blue light may be avoided.

In some embodiments, the host material BH is selected from any one of structures having following structural formulas:

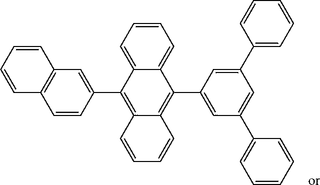

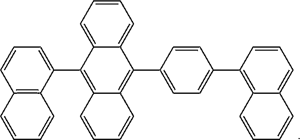

In some embodiments, the dopant material BD is selected from any one of organoboron compounds.

The organoboron compounds each take advantage of a characteristic of electron deficiency of boron to obtain a three-coordinated boron compound that is electron-defect by using a manner of sp² hybridization. In addition, due to an existence of an empty p orbital, the three-coordinated boron may generate electronic conjugation with an adjacent π system, so that the three-coordinated boron is referred to as a good acceptor unit for electrons in the excited state. A luminescent material based on an organoboron compound has a unique photoelectric property, so that a light-emitting device that emits ultra-pure blue light and has a relatively high luminous efficiency may be obtained by modifying a structure of the organoboron compound.

In some embodiments, the dopant material BD is selected from any one of structures represented by a following general formula (II).

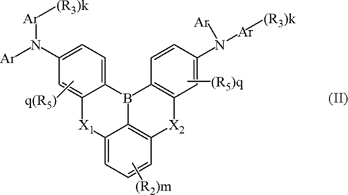

X₁ and X₂ are the same or different, and are each independently selected from any one of C(R₁)₂, N(R₁), C(═O), B(R₁), Si(R₁)₂, C(═N(R₁)), C(═C(R₁)₂), O, S, S(═O), S(═O)₂, P(R₁) and P(═O)(R₁); R₁, R₂, R₃ and R₅ are the same or different, and are each independently selected from any one of deuterium, halogen, alkyl, aryl, heteroaryl, fused aryl and fused heteroaryl; Ar is selected from any one of aryl, heteroaryl, fused aryl and fused heteroaryl; m is 0, 1 or 2, q is 0, 1 or 2, and k is 0, 1 or 2.

According to a fact that m is 0, 1 or 2, it can be seen that the number of the substituent groups R₂ may be 0, 1 or 2. In a case where the number of substituent groups R₂ is 0, there is no substituent group R₂ on a respective benzene ring, and three carbon atoms of the respective benzene ring are each bonded to hydrogen. In a case where the number of substituent groups R₂ is 1, there is one substituent group R₂ on the respective benzene ring, and two remaining carbon atoms of the respective benzene ring are each bonded to hydrogen. In a case where the number of substituent groups R₂ is 2, there is two substituent groups R₂ on the respective benzene ring, and a remaining carbon atom of the respective benzene ring is bonded to hydrogen. According to a fact that q is 0, 1 or 2, it can be seen that the number of substituent groups R₅ may be 0, 1 or 2. In a case where the number of substituent groups R₅ is 0, there is no substituent group R₅ on a respective benzene ring, and three carbon atoms of the respective benzene ring are each bonded to hydrogen. In a case where the number of substituent groups R₅ is 1, there is one substituent group R₅ on the respective benzene ring, and two remaining carbon atoms of the respective benzene ring are each bonded to hydrogen. In a case where the number of substituent groups R₅ is 2, there is two substituent groups R₅ on the respective benzene ring, and a remaining carbon atom of the respective benzene ring is bonded to hydrogen. According to a fact that k is 0, 1 or 2, it can be seen that the number of substituent groups R₃ may be 0, 1 or 2. In a case where the number of substituent groups R₃ is 0, there is no substituent group R₃ on a respective benzene ring, and five carbon atoms of the respective benzene ring are each bonded to hydrogen. In a case where the number of substituent groups R₃ is 1, there is one substituent group R₃ on the respective benzene ring, and four remaining carbon atoms of the respective benzene ring are each bonded to hydrogen. In a case where the number of substituent groups R₃ is 2, there is two substituent groups R₃ on the respective benzene ring, and three remaining carbon atoms of the respective benzene ring are each bonded to hydrogen.

In these embodiments, a blue fluorescent molecule induced by a multiple resonance effect are obtained by combining spatial structures and electronic characteristics of molecules, a structure of the blue fluorescent molecule includes a rigid polycyclic aromatic structure, and a boron atom and a heteroatom, that are para-position, of the blue fluorescent molecule may generate opposite resonance effects to enhance a molecular resonance, so that the dopant material BD has a relatively high photoluminescence quantum yield (PLQY). As a result, the device has a relatively high device efficiency.

In some embodiments, the dopant material BD is selected from any one of structures having following structural formulas:

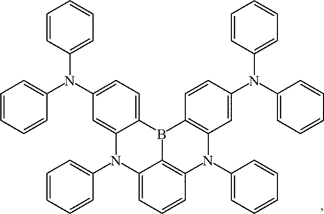

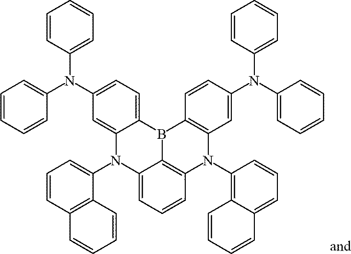

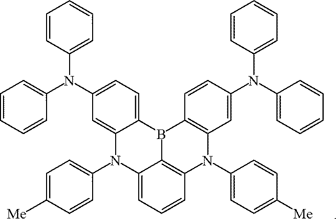

Though the research, it can be found that the dopant material BD having the above structure may emit the ultra-pure blue light and have a relatively small full width at half maximum and a relatively high device efficiency.

In some embodiments, a mass ratio of the dopant material BD to the material for forming the blue light-emitting layer may be in a range from 0.5% to 8%. At this mass ratio, the Forster energy transfer may be made sufficiently, so as to avoid a problem that it is not conducive to the Forster energy transfer due to too low doping concentration and a problem that quenching is prone to occur due to too high doping concentration.

In some embodiments, the mass ratio of the dopant material BD to the material for forming the blue light-emitting layer is in a range from 1% to 3%. For example, the mass ratio of the dopant material BD to the material for forming the blue light-emitting layer may be 1%, 2% or 3%.

In order to objectively describe technical effects of the embodiments provided in the present disclosure, the embodiments of the present disclosure will be exemplarily described in detail though a comparative example and an experimental example as follows.

It will be noted that in the comparative example and the experimental example as follows, the light-emitting devices 13 have a same structure including the anode, the hole injection layer (HIL) 136, the hole transporting layer (HTL) 134, the electron blocking layer (EBL) 138, the light-emitting layer 133, the hole blocking layer (HBL) 139, the electron transporting layer (ETL) 135, the electron injection layer (EIL) 137 and the cathode. Moreover, except the light-emitting layer 133, the same functional layers respectively in different light-emitting devices are each made of a same material. Here, ITO is selected as the material of the anodes; CuPc is selected as the material of the hole injection layers 136; N,N′-Bis-(1-naphthalenyl)-N,N′-bis-phenyl-(1,1′-biphenyl)-4,4′-diamine is selected as the material of the hole transporting layers 134; 4,4′-cyclohexylidenebis[N,N-bis(p-tolyl)aniline] is selected as the material of the electron blocking layers 138; 2,9-dimethyl-4,7-diphenyl-1,10-Phenanthroline is selected as the material of the hole blocking layer 139; LiQ₃ is selected as the material of the electron transporting layers 135; LiF is selected as the material of the electron injection layers 137; the Mg-Ag alloy is selected as the material of the cathodes.

### Comparative Example

In the comparative example, in the light-emitting layer 133, a following structure (III) is selected as a host material BH′, another following structure (IV) is selected as a dopant material BD′, and a normalized fluorescence emission spectrum of the host material BH′ and a normalized absorption spectrum of the dopant material BD′ are both as shown in FIG. 4.

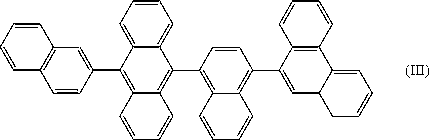 [SMILES: C1=CCC2C=C(c3ccc(-c4c5ccccc5c(-c5ccc6ccccc6c5)c5ccccc45)c4ccccc34)c3ccccc3C2=C1]

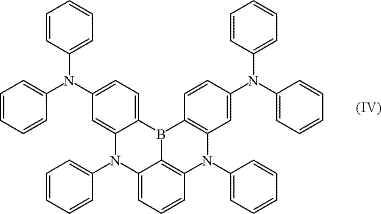 [SMILES: c1ccc(N(c2ccccc2)c2ccc3c(c2)N(c2ccccc2)c2cccc4c2B3c2ccc(N(c3ccccc3)c3ccccc3)cc2N4c2ccccc2)cc1]

### Experimental Example

In the experimental example, in the light-emitting layer 133, a dopant material BD is the same as the dopant material BD in the comparative example, a following structure (V) is selected as a host material BH, and a normalized fluorescence emission spectrum of the host material BH and a normalized absorption spectrum of the dopant material BD are both as shown in FIG. 3.

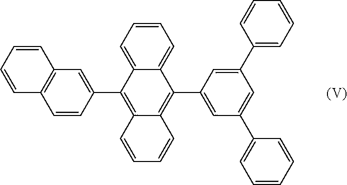 [SMILES: c1ccc(-c2cc(-c3ccccc3)cc(-c3c4ccccc4c(-c4ccc5ccccc5c4)c4ccccc34)c2)cc1]

Performance tests are performed on the light-emitting devices 13 manufactured in the comparative example and the experimental example, respectively. Test results are as shown in Table 1 below.

TABLE 1

| Device | Voltage/V | Efficiency/cd/cm² | Lifetime/h |
|---|---|---|---|
| Comparative example | 100% | 100% | 100% |
| Experimental example | 99% | 109% | 102% |

It can be seen from FIG. 4 that in the related art, an integral area of an overlapping region Y of the normalized fluorescence emission spectrum of the host material BH′ and the normalized absorption spectrum of the dopant material BD′ is relatively small and less than 50% of an integral area of the normalized fluorescence emission spectrum of the host material BH′, which is not conducive to realizing sufficient Foster energy transfer from the host material BH′ to the dopant material BD′. It can be seen from FIG. 3 that in the embodiments of the present disclosure, the integral area of the overlapping region X of the normalized fluorescence emission spectrum of the host material BH and the normalized absorption spectrum of the dopant material BD is greater than or equal to 50% of the integral area of the normalized fluorescence emission spectrum of the host material BH. Therefore, the Forster energy transfer from the host material BH to the dopant material BD may be made sufficiently, thereby greatly improving the luminous efficiency.

Moreover, in the embodiments of the present disclosure, in a case where the dopant material BD is the same as the dopant material BD′ in the related art, a fluorescence emission spectrum of the host material BH may be adjusted by adjusting the substituent groups of the host material BH. For example, with reference to FIGS. 3 and 4, it can be seen that compared with a case in which the integral area of the overlapping region Y of the normalized fluorescence emission spectrum of the host material BH′ and the normalized absorption spectrum of the dopant material BD′ is less than 50% of the integral area of the normalized fluorescence emission spectrum of the host material BH′ in the related art, in the embodiments of the present disclosure, the integral area of the overlapping region X of the normalized fluorescence emission spectrum of the host material BH and the normalized absorption spectrum of the dopant material BD is greater than or equal to 50% of the integral area of the normalized fluorescence emission spectrum of the host material BH.

Based on the above, with reference to FIGS. 3 and 4 and Table 1, it can be seen that that in a case where the integral area of the overlapping region X of the normalized fluorescence emission spectrum of the host material BH and the normalized absorption spectrum of the dopant material BD is greater than or equal to 50% of the integral area of the normalized fluorescence emission spectrum of the host material BH, the device efficiency may be greatly improved. According to a fact that the dopant material BD may be the fluorescent luminescent material, it can be seen that the host material BH may effectively transfer energy to the dopant material BD through the mechanism of the Forster energy transfer. In addition, by reasonably selecting structures of the host material BH and the dopant material BD and adjusting energy level structures of the host material BH and the dopant material BD, an exciton recombination zone in the light-emitting layer may be improved, so as to prolong the lifetime.

In summary, by selecting the host material BH and the dopant material BD and adjusting luminescence properties of the host material BH and the dopant material BD, the integral area of the overlapping region X of the normalized fluorescence emission spectrum of the host material BH and the normalized absorption spectrum of the dopant material BD is caused to be greater than or equal to 50% of the integral area of the normalized fluorescence emission spectrum of the host material BH, so that the Foster energy transfer between molecules may be used for realizing a sufficient use of energy of singlet-state excitons. As a result, the luminous efficiency of the device may be improved. Thus, a problem that it is not conducive to improving the device efficiency caused by a fact that the host material BH and the dopant material BD in the related art cannot realize the sufficient Foster energy transfer is solved.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

What is claimed is:

1. A material for forming a blue light-emitting layer, comprising:
a host material; and
a dopant material doped in the host material;
wherein a normalized fluorescence emission spectrum of the host material and a normalized absorption spectrum of the dopant material have an overlapping region therebetween, an integral area of the overlapping region is greater than or equal to 50% of an integral area of the normalized fluorescence emission spectrum of the host material, and an absolute value of a difference between a wavelength corresponding to a peak of the normalized fluorescence emission spectrum of the host material and a wavelength corresponding to a peak of the normalized absorption spectrum of the dopant material is less than or equal to 30 nm.

2. The material for forming the blue light-emitting layer according to claim 1, wherein
the wavelength corresponding to the peak of the normalized fluorescence emission spectrum of the host material is less than or equal to the wavelength corresponding to the peak of the normalized absorption spectrum of the dopant material.

3. The material for forming the blue light-emitting layer according to claim 1, wherein
a wavelength of the normalized fluorescence emission spectrum of the host material is in a range from 410 nm to 450 nm; and
a wavelength of the normalized absorption spectrum of the dopant material is in a range from 430 nm to 455 nm.

4. The material for forming the blue light-emitting layer according to claim 1, wherein
the host material is selected from any one of derivatives of anthracene.

5. The material for forming the blue light-emitting layer according to claim 4, wherein
the host material is selected from any one of structures represented by a following general formula (I): 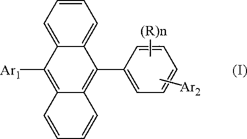
wherein Ar
₁ and Ar₂ are the same or different, and are each independently selected from any one of aryl, heteroaryl, fused aryl and fused heteroaryl; R is selected from any one of deuterium, halogen, alkyl, aryl, heteroaryl, fused aryl and fused heteroaryl; n is 0, 1 or 2.

6. The material for forming the blue light-emitting layer according to claim 5, wherein
in a case where Ar₁ is selected from heteroaryl or fused heteroaryl, the heteroaryl and the fused heteroaryl each contain no nitrogen atom;
in a case where Ar₂ is selected from heteroaryl or fused heteroaryl, the heteroaryl and the fused heteroaryl each contain no nitrogen atom;
in a case where R is selected from heteroaryl or fused heteroaryl, the heteroaryl and the fused heteroaryl each contain no nitrogen atom.

7. The material for forming the blue light-emitting layer according to claim 6, wherein
the host material is selected from any one of structures having following structural formulas: 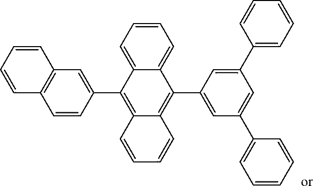 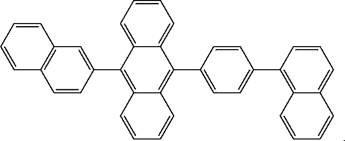
.

8. The material for forming the blue light-emitting layer according to claim 1, wherein
the dopant material is selected from any one of organoboron compounds.

9. The material for forming the blue light-emitting layer according to claim 8, wherein
the dopant material is selected from any one of structures represented by a following general formula (II): 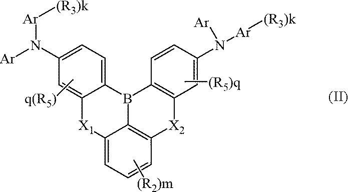
wherein X
₁ and X₂ are the same or different, and are each independently selected from any one of C(R₁)₂, N(R₁), C(═O), B(R₁), Si(R₁)₂, C(═N(R₁)), C(═C(R₁)₂), O, S, S(═O), S(═O)₂, P(R₁) and P(═O)(R₁); R₁, R₂, R₃ and R₅ are the same or different, and are each independently selected from any one of deuterium, halogen, alkyl, aryl, heteroaryl, fused aryl and fused heteroaryl; Ar is selected from any one of aryl, heteroaryl, fused aryl and fused heteroaryl; m is 0, 1 or 2, q is 0, 1 or 2, and k is 0, 1 or 2.

10. The material for forming the blue light-emitting layer according to claim 9, wherein
the dopant material is selected from any one of structures having following structural formulas: 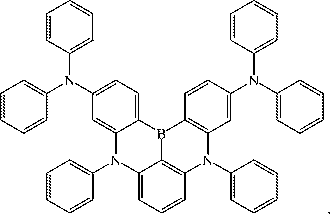 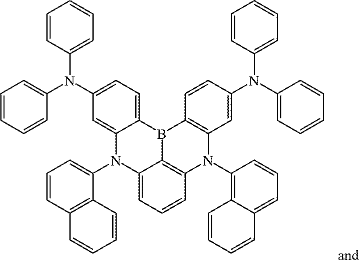 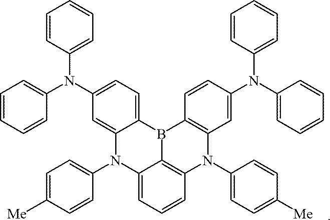
.

11. The material for forming the blue light-emitting layer according to claim 1, wherein
a mass ratio of the dopant material to the material for forming the blue light-emitting layer is in a range from 0.5% to 8%.

12. The material for forming the blue light-emitting layer according to claim 11, wherein
the mass ratio of the dopant material to the material for forming the blue light-emitting layer is in a range from 1% to 3%.

13. A light-emitting device, comprising:
a first electrode and a second electrode that are arranged sequentially; and
a light-emitting layer disposed between the first electrode and the second electrode;
wherein the material for forming the blue light-emitting layer according to claim 1 is selected as a material of the light-emitting layer.

14. A light-emitting substrate, comprising:
a substrate; and
a plurality of light-emitting devices disposed on the substrate;
wherein at least one light-emitting device of the plurality of light-emitting devices is the light-emitting device according to claim 13.

15. A light-emitting apparatus, comprising the light-emitting substrate according to claim 14.

16. The light-emitting device according to claim 13, wherein
the wavelength corresponding to the peak of the normalized fluorescence emission spectrum of the host material is less than or equal to the wavelength corresponding to the peak of the normalized absorption spectrum of the dopant material.

17. The light-emitting device according to claim 13, wherein
a wavelength of the normalized fluorescence emission spectrum of the host material is in a range from 410 nm to 450 nm; and
a wavelength of the normalized absorption spectrum of the dopant material is in a range from 430 nm to 455 nm.

18. The light-emitting device according to claim 13, wherein
the host material is selected from any one of derivatives of anthracene.

19. The light-emitting device according to claim 18, wherein
the host material is selected from any one of structures represented by a following general formula (I): 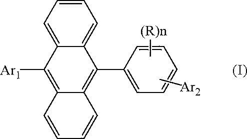
wherein Ar
₁ and Ar₂ are the same or different, and are each independently selected from any one of aryl, heteroaryl, fused aryl and fused heteroaryl; R is selected from any one of deuterium, halogen, alkyl, aryl, heteroaryl, fused aryl and fused heteroaryl; n is 0, 1 or 2.

20. The light-emitting device according to claim 19, wherein
in a case where Ar₁ is selected from heteroaryl or fused heteroaryl, the heteroaryl and the fused heteroaryl each contain no nitrogen atom;
in a case where Ar₂ is selected from heteroaryl or fused heteroaryl, the heteroaryl and the fused heteroaryl each contain no nitrogen atom;
in a case where R is selected from heteroaryl or fused heteroaryl, the heteroaryl and the fused heteroaryl each contain no nitrogen atom.
